(19) United States
(12) Patent Application Publication
(10) Pub. No.: US 2024/0106189 A1
(43) Pub. Date: Mar. 28, 2024

(54) CHIP ON SUBMOUNT

(71) Applicant: FURUKAWA ELECTRIC CO., LTD., Tokyo (JP)

(72) Inventors: Yasumasa KAWAKITA, Tokyo (JP); Masakazu MIURA, Tokyo (JP); Hirotatsu ISHII, Chiba (JP); Tetsuya TAKEUCHI, Chiba (JP)

(73) Assignee: FURUKAWA ELECTRIC CO., LTD., Tokyo (JP)

(21) Appl. No.: 18/534,857

(22) Filed: Dec. 11, 2023

Related U.S. Application Data
(63) Continuation of application No. PCT/JP2022/023669, filed on Jun. 13, 2022.

(30) Foreign Application Priority Data
Feb. 8, 2022 (JP) 2022-018254

(51) Int. Cl. H01S 5/023; H01S 5/02345

(52) U.S. Cl. CPC H01S 5/023; H01S 5/02345

(57) ABSTRACT

A chip on submount includes: a submount including a first surface directed in a first direction; a covering layer mounted on the first surface, extending to intersect the first direction, and including a second surface directed in the first direction; a laser element mounted on the second surface and including: a third surface directed in the first direction; and a light emission unit positioned at an intermediate portion of the laser element along a second direction intersecting the first direction, extending in a third direction intersecting the first direction and second direction, and configured to output laser light in the third direction; and a bonding wire attached onto the third surface and configured to exert a pressing force on the laser element, the pressing force including a component force directed in a direction opposite to the first direction.

This application is a continuation of International Application No. PCT/JP2022/023669, filed on Jun. 13, 2022 which claims the benefit of priority of the U.S. provisional patent application No. 63/210,704, filed on Jun. 15, 2021, and the prior Japanese Patent Application No. 2022-018254, filed on Feb. 8, 2022, the entire contents of which are incorporated herein by reference.

### BACKGROUND

The present disclosure relates to a chip on submount.

There has been known a chip on submount including a covering layer, which is a conductor, on a submount and a laser element mounted on the covering layer by means of solder, such as a AuSn alloy (for example, Japanese Patent No. 5075165 and Japanese Patent No. 6928560).

### SUMMARY

The inventors have found that in this type of chip on submount, polarization rotation (displacement) of laser light output from the laser element may occur depending on, for example, a position on the submount, the position being where the laser element is mounted, or a position on the laser element, the position being where the bonding wire is attached, and desired optical properties may thus be difficult to be obtained.

Accordingly, there is a need for an improved chip on submount that enables reduction of polarization rotation caused by mounting of components in the chip on submount.

According to one aspect of the present disclosure, there is provided a chip on submount including: a submount including a first surface directed in a first direction; a covering layer mounted on the first surface, extending to intersect the first direction, and including a second surface directed in the first direction; a laser element mounted on the second surface and including: a third surface directed in the first direction; and a light emission unit positioned at an intermediate portion of the laser element along a second direction intersecting the first direction, extending in a third direction intersecting the first direction and second direction, and configured to output laser light in the third direction; and a bonding wire attached onto the third surface and configured to exert a pressing force on the laser element, the pressing force including a component force directed in a direction opposite to the first direction, wherein a residual stress that causes compression toward a center of the covering layer along the second direction has been generated in the covering layer, and the chip on submount is configured such that a first moment generated by an external force acting on the laser element from the covering layer due to the residual stress and a second moment generated by the pressing force acting on the laser element from the bonding wire lessen each other, the first moment and second moment being about a central axis of the light emission unit, the central axis being along the third direction.

According to another aspect of the present disclosure, there is provided a chip on submount including: a submount including a first surface directed in a first direction; a covering layer mounted on the first surface, extending to intersect the first direction, and including a second surface directed in the first direction; a laser element mounted on the second surface and including: a third surface directed in the first direction; and a light emission unit positioned at an intermediate portion of the laser element along a second direction intersecting the first direction, extending in a third direction intersecting the first direction and second direction, and configured to output laser light in the third direction; and a bonding wire attached onto the third surface and configured to exert a pressing force on the laser element, the pressing force including a component force directed in a direction opposite to the first direction, wherein a residual stress that causes compression toward a center of the covering layer along the second direction has been generated in the covering layer, and a total of a first moment and a second moment is approximately 0, the first moment being generated by an external force acting on the laser element from the covering layer due to the residual stress, the first moment and second moment being about a central axis of the light emission unit, the central axis being along the third direction, the second moment being generated by the pressing force acting on the laser element from the bonding wire.

According to still another aspect of the present disclosure, there is provided a chip on submount including: a submount including a first surface directed in a first direction; a covering layer mounted on the first surface, extending to intersect the first direction, and including a second surface directed in the first direction; a laser element mounted on the second surface and including: a third surface directed in the first direction; and a light emission unit positioned at an intermediate portion of the laser element along a second direction intersecting the first direction, extending in a third direction intersecting the first direction and second direction, and configured to output laser light in the third direction; and a bonding wire attached onto the third surface and configured to exert a pressing force on the laser element, the pressing force including a component force directed in a direction opposite to the first direction, wherein the light emission unit is displaced in a fourth direction from the center of the covering layer along the second direction, the fourth direction being one of the second direction and a direction opposite to the second direction, and a pressing position where the bonding wire presses the third surface is displaced in a direction opposite to the fourth direction from the light emission unit.

According to yet another aspect of the present disclosure, there is provided a chip on submount including: a submount including a first surface directed in a first direction; a covering layer mounted on the first surface, extending to intersect the first direction, and including a second surface directed in the first direction; a laser element mounted on the second surface and including: a third surface directed in the first direction; and a light emission unit positioned at an intermediate portion of the laser element along a second direction intersecting the first direction, extending in a third direction intersecting the first direction and second direction, and configured to output laser light in the third direction; and a bonding wire attached onto the third surface and configured to exert a pressing force on the laser element, the pressing force including a component force directed in a direction opposite to the first direction, wherein a barycentric position, along the second direction, of a pressing position where the bonding wire presses the third surface, the light emission unit and the center of the covering layer along the second direction are aligned with one another along the first direction.

### BRIEF DESCRIPTION OF THE DRAWINGS

FIG. 1 is an exemplary and schematic front view of a chip on submount according to a first embodiment;

FIG. 2 is an exemplary and schematic front view of a chip on submount according to a second embodiment;

FIG. 3 is an exemplary and schematic front view of a chip on submount according to a third embodiment;

FIG. 4 is an exemplary and schematic front view of a chip on submount according to a fourth embodiment; and

FIG. 5 is an exemplary and schematic front view of a chip on submount according to a fifth embodiment.

### DETAILED DESCRIPTION

Exemplary embodiments will be disclosed hereinafter. Configurations of the embodiments and functions and results (effects) brought about by these configurations described hereinafter are just examples. The present disclosure may be implemented by configurations other than those disclosed hereinafter with respect to the embodiments. Furthermore, the present disclosure achieves at least one of various effects (including derivative effects) achieved by these configurations.

The embodiments described hereinafter include the same configuration. Therefore, the configurations of the embodiments achieve the same functions and effects based on that same configuration. Furthermore, the same reference signs will hereinafter be assigned to that same configuration and any redundant description thereof may be omitted.

In each drawing, an X direction is represented by an arrow X, a Y direction by an arrow Y, and a Z direction by an arrow Z. The X direction, the Y direction, and the Z direction intersect one another and are orthogonal to one another. The X direction is an outgoing direction of laser light from a laser element and is also along a longitudinal direction of the laser element. The Y direction is along a width direction of the laser element. The Z direction is a direction, in which a submount, a covering layer, and the laser element are layered, and is also referred to as a thickness direction.

The drawings are schematic and dimensions in the drawings may be different from the actual dimensions.

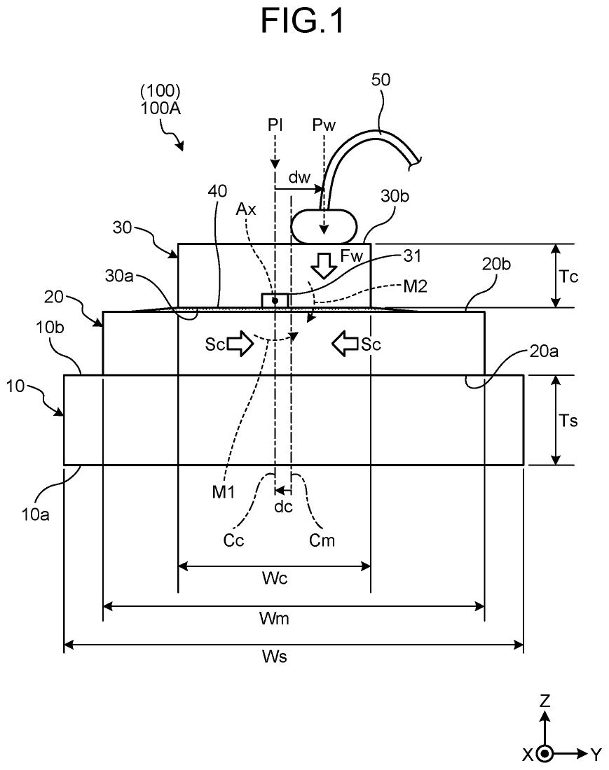

FIG. 1 is a front view of a chip on submount 100A (100) according to a first embodiment, the chip on submount 100A (100) being viewed in a direction opposite to the X direction. As illustrated in FIG. 1, the chip on submount 100A includes a submount 10, a covering layer 20, a semiconductor laser chip 30, and a bonding wire 50. The semiconductor laser chip 30 is an example of a laser element.

With a thickness that is along the Z direction and that is approximately constant, the submount 10 extends to intersect and be orthogonal to the Z direction. The submount 10 has a surface 10a and a surface 10b that is on the opposite side of the surface 10a. The surface 10a is directed in a direction opposite to the Z direction and intersects and is orthogonal to the Z direction. The surface 10b is directed in the Z direction and intersects and is orthogonal to the Z direction. The surface 10a is also referred to as a back surface and the surface 10b is also referred to as a front surface. The surface 10b is an example of a first surface. The Z direction is an example of a first direction.

The submount 10 has a thickness of about, for example, 0.3 to 1.0 mm. A material or materials for the submount 10 may include, for example, at least any one selected from a group including: aluminum nitride (AlN); alumina (Al₂O₃); beryllia (BeO); boron nitride (BN); diamond; silicon nitride (Si₃N₄); silicon carbide (SiC); silicon dioxide (SiO₂); and zirconia (ZrO₂). Aluminum nitride, silicon nitride, and silicon carbide respectively have thermal expansion coefficients of 4.5×10⁻⁶/K, 2.8×10⁻⁶/K, and 3.7×10⁻⁶/K.

The covering layer 20 is mounted on the surface 10b of the submount 10. With a thickness that is along the Z direction and that is approximately constant, the covering layer 20 extends to intersect and be orthogonal to the Z direction. The covering layer 20 has a surface 20a and a surface 20b that is on the opposite side of the surface 20a. The surface 20a is directed in the direction opposite to the Z direction and intersects and is orthogonal to the Z direction. The surface 20b is directed in the Z direction and intersects and is orthogonal to the Z direction. The surface 20a is also referred to as a back surface and the surface 20b is also referred to as a front surface. The surface 20b is an example of a second surface.

The covering layer 20 has a thickness of about, for example 20 to 200 μm. The covering layer 20 is made of, for example, a copper based material. Copper has a thermal expansion coefficient of 17×10⁻⁶/K. The thermal expansion coefficient of the covering layer 20 is larger than the thermal expansion coefficient of the submount 10. The covering layer 20 may also be referred to as an intermediate layer, a covering member, or an intermediate member.

Another covering layer (not illustrated in the drawings) that is different from the covering layer 20 is also provided on the surface 10b of the submount 10. This other covering layer and the covering layer 20 are both conductors made of the above mentioned material. The covering layer 20 and the other covering layer are separated from each other via a gap (interval) and electrically insulated from each other. The covering layer 20 and the other covering layer each have a multi-layer film made of the above mentioned copper based material. The submount 10 according to the embodiment may also be referred to as a substrate, and a substrate (the submount 10 according to the embodiment) including a covering layer may also be referred to as a submount.

The semiconductor laser chip 30 is mounted on the surface 20b of the covering layer 20 via a binder 40 having electric conductivity. The binder 40 is for example, AuSn solder. The binder 40 joins the covering layer 20 and the semiconductor laser chip 30 to each other by being heated to a temperature higher than its melting point in a reflow process and being solidified by being cooled to about room temperature.

With a thickness that is along the Z direction and that is approximately constant, the semiconductor laser chip 30 extends to intersect and be orthogonal to the Z direction. The semiconductor laser chip 30 has a surface 30a and a surface 30b that is on the opposite side of the surface 30a. The surface 30a is directed in the direction opposite to the Z direction and intersects and is orthogonal to the Z direction. The surface 30b is directed in the Z direction and intersects and is orthogonal to the Z direction.

The semiconductor laser chip 30 has a light emission unit 31 that outputs laser light in the X direction. The light emission unit 31 is positioned at an intermediate portion of the semiconductor laser chip 30 along the Y direction, the intermediate portion being at a center Cc of the semiconductor laser chip 30 along the Y direction in this embodiment, and the light emission unit 31 extends in the X direction. The light emission unit 31 is positioned closer to the surface 30a than the center of the semiconductor laser chip 30 along the Z direction is, and specifically, the light emission unit 31 is positioned near the surface 30a. The surface 30a is also referred to as a front surface and the surface 30b is also referred to as a back surface. The surface 30b is an example of a third surface. The light emission unit 31 is also referred to as an active layer. The semiconductor laser chip 30 according to this embodiment is mounted junction-down. The intermediate portion of the semiconductor laser chip 30 along the Y direction means a portion between an end of the semiconductor laser chip 30 and an opposite end of the semiconductor laser chip 30, the end being in the Y direction, the opposite end being in a direction opposite to the Y direction. The Y direction is an example of a second direction, and the X direction is an example of a third direction.

The covering layer 20 is electrically connected, via the binder 40, to an electrode (for example, a p-type electrode not illustrated in the drawings) provided on the surface 30a of the semiconductor laser chip 30. The above mentioned other layer on the surface 10b is electrically connected, via the bonding wire 50, to an electrode (for example, an n-type electrode not illustrated in the drawings) provided on the surface 30b of the semiconductor laser chip 30. The bonding wire 50 is joined and electrically connected, via a binder, such as AuSn solder, to an electrode provided on the surface 30b.

The semiconductor laser chip 30 outputs laser light having a wavelength according to its configuration and material/materials. The semiconductor laser chip 30 has a thickness of, for example, about 0.1 mm. The semiconductor laser chip 30 may include components, such as, for example, gallium arsenide (GaAs) and/or indium phosphide (InP). Gallium arsenide and indium phosphide respectively have thermal expansion coefficients of 5.9×10⁻⁶/K and 4.5×10⁻⁶/K.

The thermal expansion coefficient of the covering layer 20 in the chip on submount 100A (100) having the above described configuration is larger than the thermal expansion coefficient of the submount 10, and the covering layer 20 thus contracts more largely than the submount 10 during cooling in the reflow process for the binder 40. Therefore, a residual stress Sc is generated in the covering layer 20, the residual stress Sc causing compression in the covering layer 20, the compression being toward a center Cm of the covering layer 20 along the Y direction in the view of FIG. 1, that is, in the front view of the chip on submount 100 as viewed in the direction opposite to the X direction.

This residual stress Sc acts as an external force on the surface 30a of the semiconductor laser chip 30 via the surface 20b and the binder 40. The external force may cause a moment M1 to act on the light emission unit 31, the moment M1 being about a central axis Ax of the light emission unit 31, the central axis Ax extending in the X direction. In the example of FIG. 1, the light emission unit 31 is at a position P1 displaced in the direction opposite to the Y direction from the center Cm of the covering layer 20 along the Y direction. A residual stress that causes compression in the covering layer 20 in the Y direction toward the center Cm is generated in a portion of the covering layer 20, the portion being more rearward (leftward in FIG. 1) than the center Cm along the Y direction. Therefore, an external force in the Y direction (rightward in FIG. 1) acts on a portion of the surface 30a of the semiconductor laser chip 30, the portion being near the light emission unit 31 and being behind (below in FIG. 1) the light emission unit 31 along the Z direction. In this case, the external force causes the moment M1 to act on the light emission unit 31, the moment M1 being in an anticlockwise direction in FIG. 1. The moment M1 is an example of a first moment. In the example of FIG. 1, the direction opposite to the Y direction is an example of a fourth direction. A residual stress that causes compression in the covering layer 20 in the direction opposite to the Y direction toward the center Cm is also generated in a portion of the covering layer 20, the portion being more forward (rightward in FIG. 1) than the center Cm along the Y direction.

Furthermore, a pressing force Fw that presses the semiconductor laser chip 30 toward the covering layer 20 and submount 10 acts from the bonding wire 50, in the chip on submount 100A (100) having the above described configuration. This pressing force Fw includes a component force in the direction opposite to the Z direction (downward in FIG. 1).

The pressing force Fw may cause a moment M2 to act on the light emission unit 31, the moment M2 being about the central axis Ax of the light emission unit 31. In the example of FIG. 1, the position where the bonding wire 50 presses the surface 30b of the semiconductor laser chip 30, that is, a connection position Pw between the bonding wire 50 and the surface 30b is displaced, by a displacement dw in the Y direction (rightward in FIG. 1), from the position P1 (the same position as the center Cc of the semiconductor laser chip 30 along the Y direction in this embodiment) of the light emission unit 31 (central axis Ax) along the Y direction. In this case, the pressing force Fw causes the moment M2 to act on the light emission unit 31, the moment M2 being in the anticlockwise direction in FIG. 1. The moment M2 is an example of a second moment. In the example of FIG. 1, the Y direction is an example of a direction opposite to the fourth direction.

The inventors have found that laser light output from the semiconductor laser chip 30 changes in polarization angle according to the connection position Pw of the bonding wire 50 along the Y direction. Specifically, the inventors manufactured a large number of semiconductor laser chips 30 having different connection positions Pw along the Y direction and studied relations between displacements dw of the connection positions Pw from the centers Cc of the semiconductor laser chips 30 along the Y direction and polarization rotation angles (rotational displacements from a desired state) of laser light output by the semiconductor laser chips 30. The displacement dw is a manufacture target value and includes a tolerance range. In a case where the connection position Pw is displaced in the Y direction from the center Cc, the displacement dw has a positive sign (+) and in a case where the connection position Pw is displaced in the direction opposite to the Y direction, the displacement dw has a negative sign (−). In the example of FIG. 1, the center Cc of the semiconductor laser chip 30 along the Y direction is the position P1 of the light emission unit (central axis Ax) along the Y direction. Experimental results were obtained as follows.

### Experimental Results

In a case where dw=+30 μm, polarization rotation angle: 0 to 15 degrees (evaluation: excellent)

In a case where dw=+15 μm, polarization rotation angle: −10 to 0 degrees (evaluation: excellent)

In a case where dw=0 μm, polarization rotation angle: −20 to −5 degrees (evaluation: good)

In a case where dw=−15 μm, polarization rotation angle: −30 to −10 degrees (evaluation: satisfactory)

In a case where dw=−30 μm, polarization rotation angle: −50 to −35 degrees (evaluation: unsatisfactory)

These experimental results indicated that the larger the displacement dw is, the larger the polarization rotation angle is. The experimental results also indicated that the polarization angle is minimized when dw=+15 to +30, and not when dw=0. Analysis by the inventors indicated that this is because the position P1 of the light emission unit 31 along the Y direction was displaced in the direction opposite to the Y direction from the center Cm of the covering layer 20 along the Y direction (the displacement of the position P1 from the center Cm:dc, see FIG. 1).

Accordingly, configuring the chip on submount 100A such that the above described moment M1 generated by the residual stress Sc and the above described moment M2 generated by the pressing force Fw lessen each other presumably enables obtainment of the semiconductor laser chip 30 having reduced polarization rotation from desired properties and having excellent optical properties.

In this embodiment, as described above, the position P1 of the light emission unit 31 is displaced in the direction (fourth direction) opposite to the Y direction from the center Cm of the covering layer 20 along the Y direction, the connection position Pw for the bonding wire 50 is displaced in the Y direction (the direction opposite to the fourth direction) from the position P1 of the light emission unit 31, and polarization rotation relative to desired properties is thereby able to be reduced.

Furthermore, in this embodiment, the light emission unit 31 (central axis Ax) is positioned at the center Cc of the semiconductor laser chip 30 along the Y direction, the center Cc is thus displaced in a direction opposite to the direction of the connection position Pw from the center Cm of the covering layer 20 along the Y direction, and polarization rotation relative to desired properties is thereby able to be reduced.

Furthermore, research by the inventors revealed that the effect of reducing the polarization rotation angle by this configuration is achieved in a case where the covering layer 20 has a width Wm along the Y direction smaller than a width Ws of the submount 10 along the Y direction and larger than a width We of the semiconductor laser chip 30, and in particular, that the difference (Ws−Wm) between the width Wm and the width Ws is preferably equal to or smaller than ½ of the width Ws and is more preferably equal to or smaller than ⅓ of the width Ws. Furthermore, the inventors found that the semiconductor laser chip 30 preferably has a thickness Tc along the Z direction equal to or less than ⅓ of a thickness Ts of the submount 10 along the Z direction.

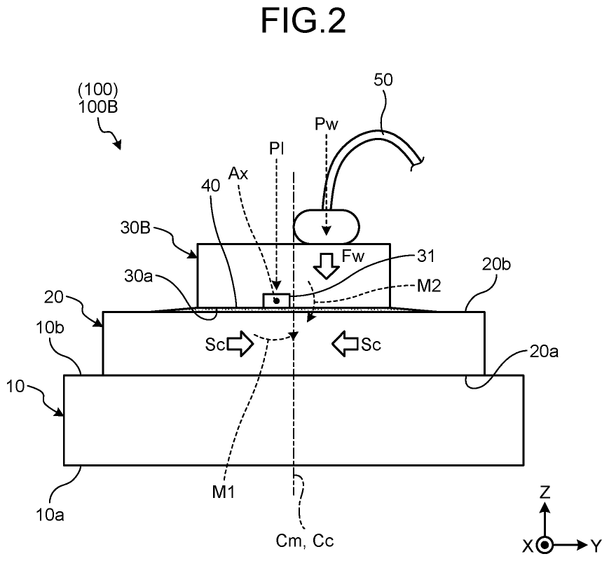

FIG. 2 is a front view of a chip on submount 100B (100) according to a second embodiment, the chip on submount 100B (100) being viewed in the direction opposite to the X direction.

The chip on submount 100B according to this embodiment includes the same configuration as the first embodiment described above. However, the position P1 of the light emission unit 31 along the Y direction in a semiconductor laser chip 30B in this embodiment is different from that in the first embodiment described above. That is, the light emission unit 31 (central axis Ax) at the semiconductor laser chip 30B in this embodiment is displaced in the direction opposite to the direction of the connection position Pw from a center Cc of the semiconductor laser chip 30B along the Y direction. In this case, by being configured such that the center Cc of the semiconductor laser chip 30B along the Y direction overlaps the center Cm of the covering layer 20 along the Y direction, the second embodiment enables obtainment of a layout similar to that of the first embodiment described above. That is, the second embodiment enables a state to be achieved comparatively readily, the state being a state where the position P1 of the light emission unit 31 is displaced in the direction (fourth direction) opposite to the Y direction from the center Cm of the covering layer 20 along the Y direction and the connection position Pw of the bonding wire 50 is displaced in the Y direction (the direction opposite to the fourth direction) from the position P1 of the light emission unit 31, that is, a state where the moment M1 and the moment M2 lessen each other. This embodiment also enables reduction of polarization rotation relative to desired properties, similarly to the first embodiment described above.

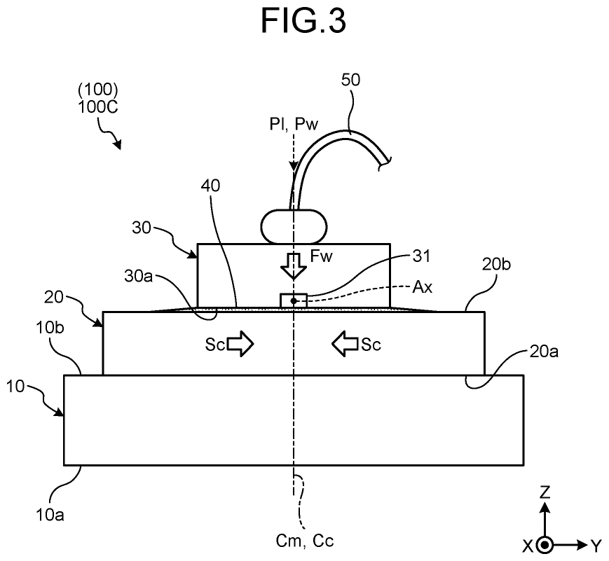

FIG. 3 is a front view of a chip on submount 100C (100) according to a third embodiment, the chip on submount 100C (100) being viewed in the direction opposite to the X direction.

The chip on submount 100C according to the third embodiment includes the same configuration as the first embodiment described above. However, in this third embodiment, the position P1 of the light emission unit 31 (central axis Ax), the connection position Pw between the bonding wire 50 and the surface 30b, and the position of the center Cm of the covering layer 20 along the Y direction are aligned with one another along the Z direction. In other words, the position P1, the connection position Pw, and the center Cm are at the same position in the Y direction. In this case, the moment M1 about the central axis Ax and due to the external force based on the residual stress Sc is not generated, the moment M2 about the central axis Ax and due to the pressing force Fw acting from the connection position Pw is also not generated because the length of the moment arm becomes approximately 0, and the total of the moment M1 and the moment M2 becomes approximately 0. Therefore, this third embodiment also enables reduction of polarization rotation relative to desired properties, similarly to the other embodiments described above. In this third embodiment, the connection position Pw may be said to be a barycentric position where the pressing force Fw acts upon.

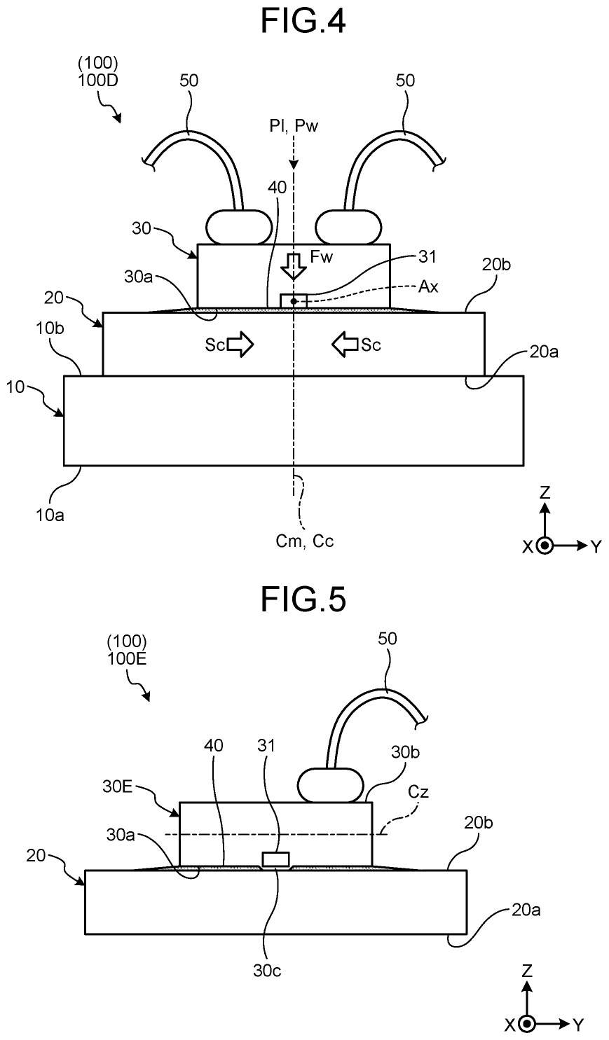

FIG. 4 is a front view of a chip on submount 100D (100) according to a fourth embodiment, the chip on submount 100D (100) being viewed in the direction opposite to the X direction.

The chip on submount 100D according to the fourth embodiment includes the same configuration as the first embodiment described above. However, in the fourth embodiment, plural bonding wires 50 are mounted, symmetrically about the center Cc along the Y direction, on the surface 30b of the semiconductor laser chip 30. A barycentric position of plural connection positions Pw along the Y direction is denoted by Pwc. In this embodiment, the position P1 of the light emission unit 31 (central axis Ax), the barycentric position Pwc, and the position of the center Cm of the covering layer 20 along the Y direction are aligned with one another along the Z direction. In other words, the position P1, the barycentric position Pwc, and the center Cm are at the same position in the Y direction. In this case, the moment M1 about the central axis Ax and due to the external force based on the residual stress Sc is not generated, the moment M2 about the central axis Ax and due to the pressing force Fw (resultant force) acting from the barycentric position Pwc is also not generated because the length of the moment arm becomes approximately 0, and the total of the moment M1 and the moment M2 becomes approximately 0. Therefore, this fourth embodiment also enables reduction of polarization rotation relative to desired properties, similarly to the other embodiments described above.

FIG. 5 is a front view of a chip on submount 100E (100) according to a fifth embodiment, the chip on submount 100E (100) being viewed in the direction opposite to the X direction.

The chip on submount 100E according to the fifth embodiment includes the same configuration as the first embodiment described above. However, in this embodiment, a semiconductor laser chip 30E is a so-called ridge-type chip having a protrusion 30c protruding, near the light emission unit 31, from a surface 30a of the semiconductor laser chip 30E. In this case, the light emission unit 31 is positioned closer to the surface 30a of the semiconductor laser chip 30E than a center Cz of the semiconductor laser chip 30E is along the Z direction, the surface 30a being an end of the semiconductor laser chip 30E, the end being in the direction opposite to the Z direction, and the protrusion 30c and the light emission unit 31 are aligned with each other along the Z direction. Research by the inventors revealed that including the same configuration as the other embodiments described above in this ridge type semiconductor laser chip 30E also enables the same effects to be achieved.

The embodiments have been described above by way of example, but the embodiments are just examples and are not intended to limit the scope of the disclosure. The above described embodiments may be implemented in various other modes, and without departing from the gist of the disclosure, various omissions, substitutions, combinations, and modifications may be made. Furthermore, the disclosure may be implemented by modifying, as appropriate, the specifications of the components and shapes (such as, the structures, types, directions, models, sizes, lengths, widths, thicknesses, heights, numbers, arrangements, positions, and materials), for example.

For example, the displacement of each component or part in the second direction from the center of the covering layer along the second direction is not limited to that in the embodiments described above and may be in a direction opposite to that in the embodiments described above.

The present disclosure enables, for example, a novel and improved chip on submount to be obtained, the chip on submount enabling reduction of polarization rotation according to a position where a component is mounted in the chip on submount.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A chip on submount comprising:
a submount including a first surface directed in a first direction;
a covering layer mounted on the first surface, extending to intersect the first direction, and including a second surface directed in the first direction;
a laser element mounted on the second surface and including:
a third surface directed in the first direction; and
a light emission unit positioned at an intermediate portion of the laser element along a second direction intersecting the first direction, extending in a third direction intersecting the first direction and second direction, and configured to output laser light in the third direction; and
a bonding wire attached onto the third surface and configured to exert a pressing force on the laser element, the pressing force including a component force directed in a direction opposite to the first direction, wherein
a residual stress that causes compression toward a center of the covering layer along the second direction has been generated in the covering layer, and
the chip on submount is configured such that a first moment generated by an external force acting on the laser element from the covering layer due to the residual stress and a second moment generated by the pressing force acting on the laser element from the bonding wire lessen each other, the first moment and second moment being about a central axis of the light emission unit, the central axis being along the third direction.

2. The chip on submount according to claim 1, wherein
the light emission unit is positioned closer to an end of the laser element in the direction opposite to the first direction than the center of the laser element along the first direction, and
the laser element includes a protrusion aligned with the light emission unit along the first direction and protruding in the direction opposite to the first direction.

3. The chip on submount according to claim 1, wherein a width of the covering layer along the second direction is smaller than a width of the submount along the second direction and larger than a width of the laser element along the second direction.

4. The chip on submount according to claim 1, wherein a thickness of the laser element in the first direction is equal to or less than ⅓ of a thickness of the submount in the first direction.

5. The chip on submount according to claim 1, wherein
the submount includes aluminum nitride, and
the covering layer includes a copper-based material.

6. The chip on submount according to claim 1, wherein
the light emission unit is displaced in a fourth direction from the center of the covering layer along the second direction, the fourth direction being one of the second direction and a direction opposite to the second direction, and
a pressing position where the bonding wire presses the third surface is displaced in a direction opposite to the fourth direction from the light emission unit.

7. The chip on submount according to claim 6, wherein the center of the laser element along the second direction is displaced in a direction opposite to a direction of the pressing position from the center of the covering layer along the second direction.

8. The chip on submount according to claim 6, wherein the light emission unit is positioned in a direction opposite to a direction of the pressing position, relatively to the center of the laser element along the second direction.

9. The chip on submount according to claim 1, wherein a pressing position where the bonding wire presses the third surface, a position of the light emission unit and the center of the covering layer along the second direction are aligned with one another along the first direction.

10. A chip on submount comprising:
a submount including a first surface directed in a first direction;
a covering layer mounted on the first surface, extending to intersect the first direction, and including a second surface directed in the first direction;
a laser element mounted on the second surface and including:
a third surface directed in the first direction; and
a light emission unit positioned at an intermediate portion of the laser element along a second direction intersecting the first direction, extending in a third direction intersecting the first direction and second direction, and configured to output laser light in the third direction; and
a bonding wire attached onto the third surface and configured to exert a pressing force on the laser element, the pressing force including a component force directed in a direction opposite to the first direction, wherein
a residual stress that causes compression toward a center of the covering layer along the second direction has been generated in the covering layer, and
a total of a first moment and a second moment is approximately 0, the first moment being generated by an external force acting on the laser element from the covering layer due to the residual stress, the first moment and second moment being about a central axis of the light emission unit, the central axis being along the third direction, the second moment being generated by the pressing force acting on the laser element from the bonding wire.

11. The chip on submount according to claim 10, wherein
the light emission unit is positioned closer to an end of the laser element in the direction opposite to the first direction than the center of the laser element along the first direction, and
the laser element includes a protrusion aligned with the light emission unit along the first direction and protruding in the direction opposite to the first direction.

12. The chip on submount according to claim 10, wherein a width of the covering layer along the second direction is smaller than a width of the submount along the second direction and larger than a width of the laser element along the second direction.

13. The chip on submount according to claim 10, wherein a thickness of the laser element in the first direction is equal to or less than ⅓ of a thickness of the submount in the first direction.

14. The chip on submount according to claim 10, wherein
the submount includes aluminum nitride, and
the covering layer includes a copper-based material.

15. The chip on submount according to claim 10, wherein
the light emission unit is displaced in a fourth direction from the center of the covering layer along the second direction, the fourth direction being one of the second direction and a direction opposite to the second direction, and
a pressing position where the bonding wire presses the third surface is displaced in a direction opposite to the fourth direction from the light emission unit.

16. The chip on submount according to claim 15, wherein the center of the laser element along the second direction is displaced in a direction opposite to a direction of the pressing position from the center of the covering layer along the second direction.

17. The chip on submount according to claim 15, wherein the light emission unit is positioned in a direction opposite to a direction of the pressing position, relatively to the center of the laser element along the second direction.

18. The chip on submount according to claim 10, wherein a pressing position where the bonding wire presses the third surface, a position of the light emission unit and the center of the covering layer along the second direction are aligned with one another along the first direction.

19. A chip on submount comprising:
a submount including a first surface directed in a first direction;
a covering layer mounted on the first surface, extending to intersect the first direction, and including a second surface directed in the first direction;
a laser element mounted on the second surface and including:
a third surface directed in the first direction; and
a light emission unit positioned at an intermediate portion of the laser element along a second direction intersecting the first direction, extending in a third direction intersecting the first direction and second direction, and configured to output laser light in the third direction; and
a bonding wire attached onto the third surface and configured to exert a pressing force on the laser element, the pressing force including a component force directed in a direction opposite to the first direction, wherein
the light emission unit is displaced in a fourth direction from the center of the covering layer along the second direction, the fourth direction being one of the second direction and a direction opposite to the second direction, and
a pressing position where the bonding wire presses the third surface is displaced in a direction opposite to the fourth direction from the light emission unit.

20. A chip on submount comprising:
a submount including a first surface directed in a first direction;
a covering layer mounted on the first surface, extending to intersect the first direction, and including a second surface directed in the first direction;
a laser element mounted on the second surface and including:
a third surface directed in the first direction; and
a light emission unit positioned at an intermediate portion of the laser element along a second direction intersecting the first direction, extending in a third direction intersecting the first direction and second direction, and configured to output laser light in the third direction; and
a bonding wire attached onto the third surface and configured to exert a pressing force on the laser element, the pressing force including a component force directed in a direction opposite to the first direction, wherein
a barycentric position, along the second direction, of a pressing position where the bonding wire presses the third surface, the light emission unit and the center of the covering layer along the second direction are aligned with one another along the first direction.
